(19) United States
(12) Patent Application Publication
(10) Pub. No.: US 2026/0141962 A1
(43) Pub. Date: May 21, 2026

(54) HYBRID DUTY CYCLE CORRECTION AND QUADRATURE ERROR CORRECTION CLOCKING CIRCUITRY

(71) Applicant: Micron Technology, Inc., Boise, ID (US)

(72) Inventors: Kwansu Shon, Boise, ID (US); Guan Wang, Boise, ID (US)

(73) Assignee: Micron Technology, Inc., Boise, ID (US)

(21) Appl. No.: 19/387,269

(22) Filed: Nov. 12, 2025

Related U.S. Application Data
(60) Provisional application No. 63/723,066, filed on Nov. 20, 2024.

(51) Int. Cl. G11C 16/32; G11C 16/04; H03K 5/156

(52) U.S. Cl. CPC G11C 16/32; G11C 16/0483; H03K 5/1565

(57) ABSTRACT

Methods, systems, and devices for techniques for four-phase clocking, and in particular, to a hybrid duty-cycle correction and quadrature error correction (DCC-QEC) circuitry are described. The DCC-QEC circuitry comprises a DCC circuit configured to generate two-phase clock signals based on external clock signals. The DCC circuit is self-calibratable without receiving a reference signal. The DCC-QEC circuitry further comprises one or more QEC circuits coupled to the DCC circuit, each of the QEC circuit comprising a pair of phase splitters configured to convert the two-phase clock signals to four-phase clock signals, and a skew adjuster configured to adjust, based on QEC adjustment codes and in an open loop manner, clock skews associated with a subset of the four-phase clock signals, in which data from multiple lanes of parallel data channels are serialized based on the skew-adjusted four-phase clock signals and transmitted to external of a device comprising the DCC-QEC circuitry.

### CROSS-REFERENCE TO RELATED APPLICATIONS

This application claims priority to U.S. Provisional Application No. 63/723,066, filed on Nov. 20, 2024, entitled “HYBRID DUTY CYCLE CORRECTION AND QUADRATURE ERROR CORRECTION CLOCKING CIRCUITRY,” the contents of which is incorporated by reference in its entirety for all purposes.

### TECHNICAL FIELD

This disclosure relates to one or more systems for memory, including techniques for four-phase clocking circuitry, and in particular, to a hybrid duty-cycle correction and quadrature error correction (DCC-QEC) circuitry.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2B are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4A is a block diagram of a hybrid DCC-QEC circuit configured to implement four-phase clocking, in accordance with examples as disclosed herein.

FIG. 4B is a block diagram of a part of a QEC circuit of the hybrid DCC-QEC circuit of FIG. 4A, in accordance with examples as disclosed herein.

FIG. 4C is a timing diagram representing four clock signals having four different phases, in accordance with examples as disclosed herein.

FIG. 5 is a timing diagram illustrating skew adjustment process for at least one traditional approach.

### DETAILED DESCRIPTION

A memory device frequently receives commands for read, write, and/or erase operations. A memory controller communicates with memory cells (e.g., NAND cells) to send instructions for such commands. The memory controller uses clocking or clock signals to cause the operations to be performed at precise timing and/or in a particular sequence. Error-corrected clocking may permit the memory device to read and write data at correct times, synchronize different operations, increase the data transmission eye opening, correct data transmission errors, etc., thereby enhancing the memory device performance (e.g., enhance the speed of data transfers) and reducing power consumption (e.g., enter low-power states during idle times). To improve and/or optimize timing and clocking, phased clocking may be used. In phased clocking, a clock signal is divided into multiple phases. A clock phase refers to the position of the clock signal in time relative to other signals or a reference clock. Each phase of the clock signal represents a different point in the clock cycle (or a time period of the clock signal). Multiple clock phases may allow more precise signal controls, improved synchronization among signals, and increased data transfer rate.

Existing phased clocking with respect to memory devices may include two-phase clocking and/or four-phase clocking. In two-phase clocking, the clock signal is divided into two phases, in which each phase corresponds to different timings within the clock cycle. The two phases permit data to be transferred on both phases, thereby improving speed and efficiency of the data transfers. For example, in memory devices, the two-phase clocking may permit faster data access time while potentially lowering power consumption. In four-phase clocking, the clock signal is divided into four phases, providing refined control over timing and operations.

To implement phased clocking, technologies and circuits have been developed. For example, duty cycle correction (DCC) circuits have been developed. DCC circuits help maintain a consistent duty cycle or a ratio of active time to the total period of the clock signal. The DCC circuits help each clock signal having a particular phase to maintain precise duty cycles. The DCC circuit may continuously monitor various phases of clock signals and assess the duty cycle of each phase. In response to detecting a duty cycle that is deviated from precise duty cycle (e.g., 50%), the DCC circuit may output an error signal indicating the deviation. The clock signal may thus be adjusted (e.g., by adjusting the voltage level) based on the error signal to have the desired duty cycle.

However, existing DCC circuits may not work well for four-phase clocking. In four-phase clocking, relationships between four phases of the clock signals are managed in a closed-loop manner, which adds to the complexity of the circuitry. For example, the four-phase clocking generally has tightened timing requirements. But the DCC circuit may introduce delays in the feedback loop and therefore the tightened timing requirements may not be satisfied. Additionally, the existing DCC circuit may not adequately account for interdependency between the phases of the four-phase clock signals. To compensate for such deficiencies of the existing DCC circuit, a quadrature edge correction (QEC) circuit may be used to implement four-phase clocking. The QEC circuit may be configured to adjust timing of clock edges to eliminate time skew and to permit transitions to occur at correct intervals. The QEC circuit may detect misalignments between the clock edges and apply corrections to help maintain phase relationships among the four clock signals. The QEC circuit continuously monitors the edges of clock phases and identifies any skews between clock phases. Based on the detected skew, the QEC circuit may adjust the edges of the clock signals such that they are aligned. However, such existing QEC circuit may face several implementation challenges or issues. For example, implementing the QEC circuit may require an increased number of components which may increase the complexity of the circuitry, power consumption, cost, etc. For example, existing QEC circuits may need components arranged in a close-loop manner to perform skew adjustments between the four clock phases. Due to the close-loop nature, the existing QEC circuit may suffer from slow operational speed (e.g., due to the loop settlement time), instability, and/or oscillations in the clock signal with the feedback loop.

Techniques and circuits described herein provide a DCC-QEC hybrid circuit, in which a DCC circuit and a QEC circuit are used together to implement four-phase clocking. The DCC-QEC hybrid circuit disclosed herein includes a DCC circuit with adopted self-calibration, such that the DCC circuit is self-calibratable without receiving a reference signal. The self-calibration of the DCC circuit may reduce calibration time and also address both internal and external duty cycle distortions together. The DCC circuit may provide calibration such that no calibration time is needed for the QEC circuit. Additionally, at least a portion of the QEC circuit is used in a test mode to control the adjustments needed for the correcting the time skew. Such use of the test mode eliminates the need for using closed-loop control present in traditional QEC circuits. Instead, the QEC circuit receives QEC adjustment codes and adjusts the time skews in an open loop manner, thereby shortening the skew adjustment time. Moreover, by eliminating closed-loop control logic, the present DCC-QEC circuitry is simpler. The DCC-QEC hybrid circuits and techniques disclosed herein can therefore enable four-phase clocking with reduced calibration time and with reduced layout area and power consumption, compared to existing QEC circuit implementing the four-phase clocking. Furthermore, the correction range and resolution of the DCC-QEC circuit can be separately optimized for external clock duty distortion and the internal four-phase time skews. The technique and circuits are further described in greater details below.

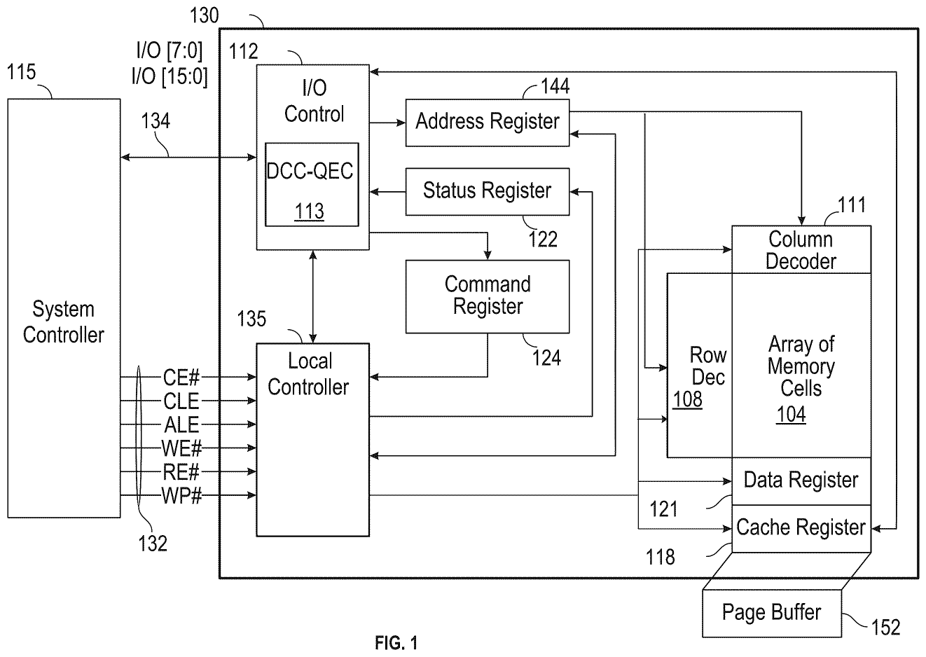

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

In some embodiments, the I/O control circuitry 112 includes a hybrid DCC-QEC circuitry 113. The hybrid DCC-QEC circuit 113 is configured to implement four-phase clocking based on external clock signals. The local controller 135 receives external clock signals (e.g., denoted as #RE) from an external clock or a system, and the I/O control circuitry 112 receives the external clock signals from the local controller 135. In one embodiment, the hybrid DCC-QEC circuit 113 is included in the I/O control circuitry 112 and/or between the I/O control circuitry 112 and the local controller 135. The hybrid DCC-QEC circuit 113 is configured to receive the external clock signals, generate two clock signals with two phases based on the external clock signals, correct the duty cycles of the two clock signals, convert the two clock signals to four clock signals with four different phases, and adjust the clock skews associated with a subset of the four clock signals.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

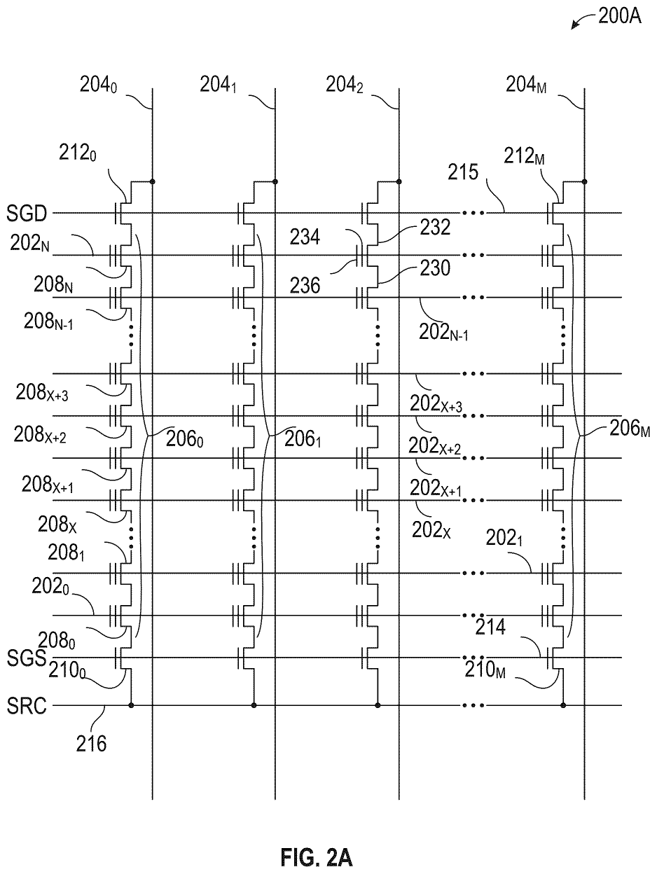

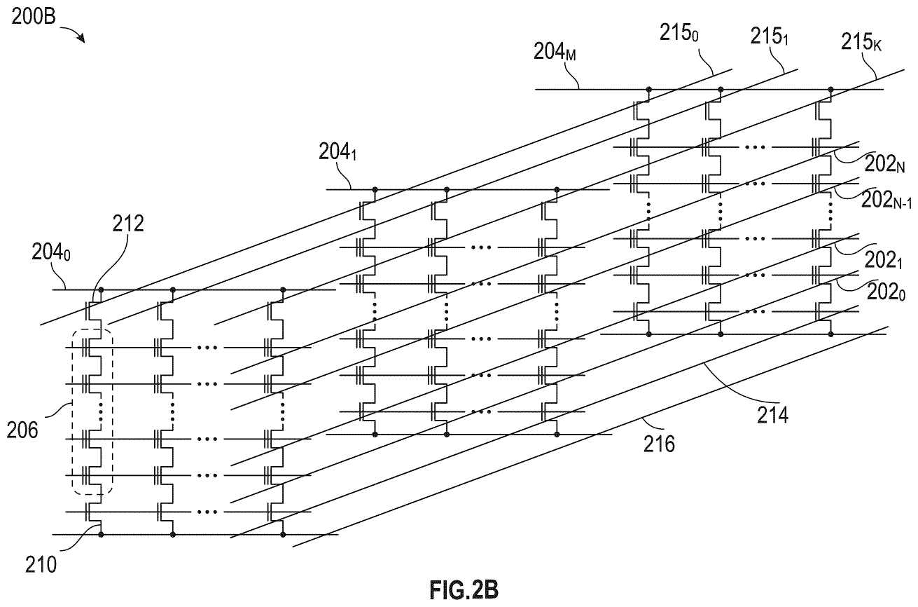

FIGS. 2A-2B are example schematics of portions of an array of memory cells 200A, such as a NAND memory array. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

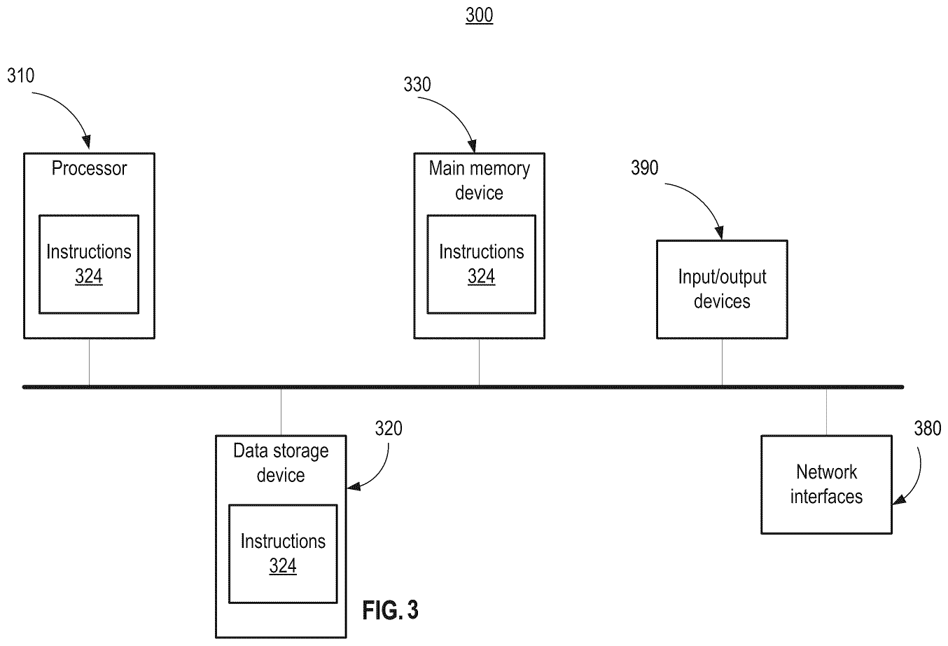

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-5, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIG. 6 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIG. 6. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

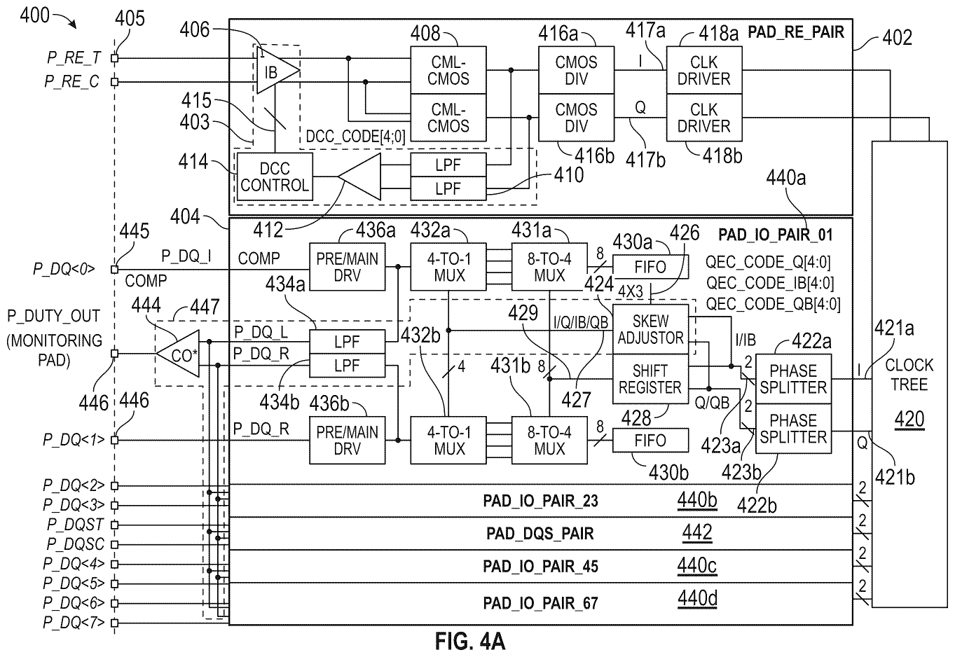

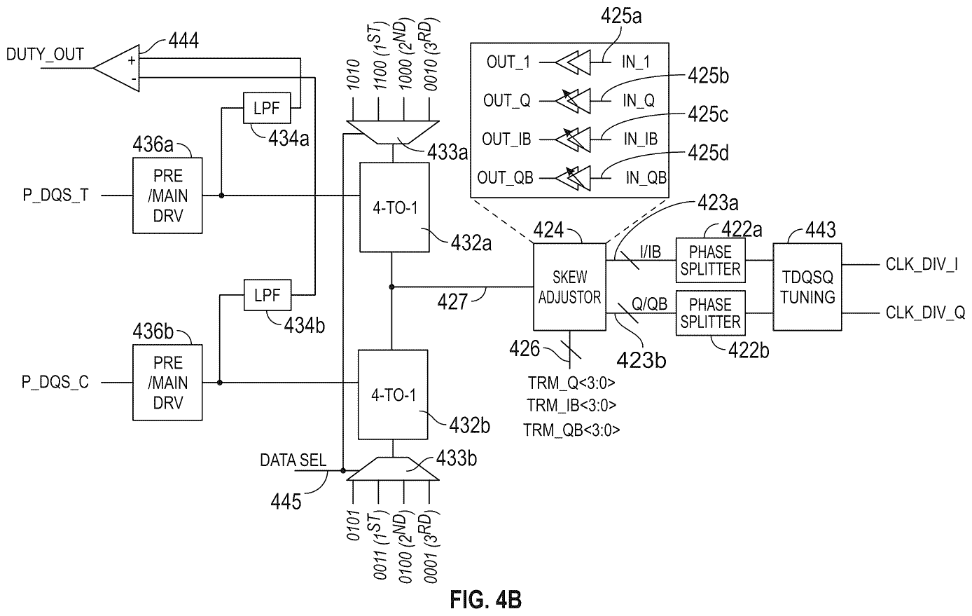

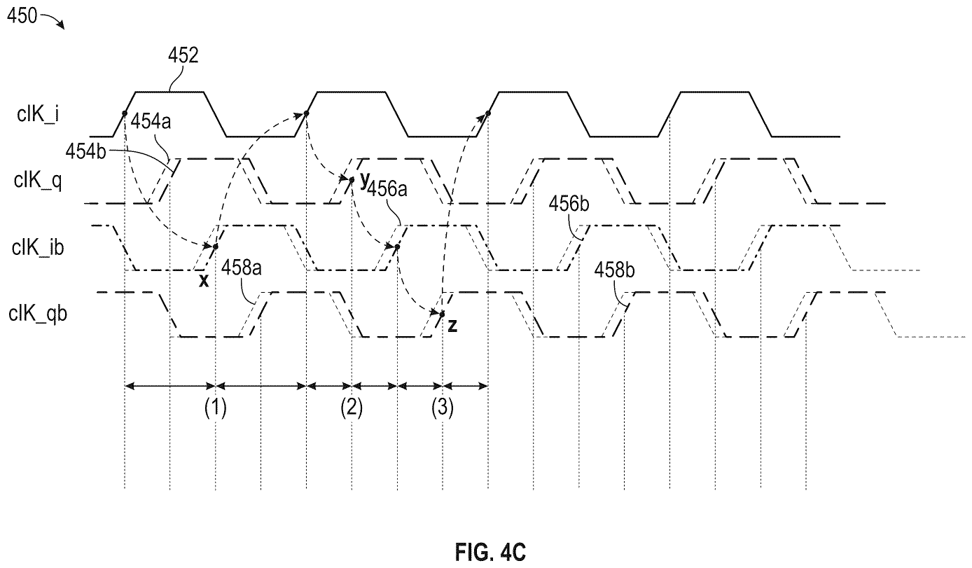

FIG. 4A illustrates an example hybrid DCC-QEC circuit 400 configured to implement four-phase clocking, in accordance with examples as disclosed herein. The DCC-QEC circuit 400 is configured to generate two clock signals having two different phases based on external clock signals, correct the duty cycles of the two clock signals, convert the two clock signals to four clock signals having four different phases, and adjust the clock skews associated with a subset of the four clock signals in an open loop manner. The DCC-QEC circuit 400 can implement four-phase clocking with reduced complexity and/or footprint. With reference to FIG. 4A, DCC-QEC circuit 400 may be used to implement DCC-QEC circuitry 113 shown in FIG. 1. As shown in FIG. 1, the DCC-QEC circuit 113 may be a part of I/O control circuit 112, or I/O circuitry of another part of memory device 130.

With reference back to FIG. 4A, in some embodiments, the DCC-QEC circuit 400 includes a DCC circuit 402, one or more QEC circuits (including a QEC circuit 404), and a clock tree 420. The DCC circuit 402 is configured to receive external clock signals 405 generated outside of the DCC-QEC circuit 400. For example, the external clock signals 405 may be obtained from an external clock, such as a dedicated clock generator. The external clock signals 405 may be provide by, for example, a host system communicating with the memory device 130. In some embodiments, the external clock signals 405 may be current-mode logic (CML) clock signals. CML signals use currents instead of voltages to represent the states of the signals. Typically, a constant current flows through the CML logic circuit and one or more differential pairs of transistors steer the current between two outputs. Thus, CML logic circuit uses differential signaling, improving noise immunity (e.g., rejects common mode noise) and minimizing interference. In some examples, CML signals may have smaller signal swing (e.g., voltage swing) compared to CMOS logic signals. For example, the external clock signals 405 may have 200 mV swing, compared to the 1.2 V swing for CMOS logic signals used inside the memory device 130 of FIG. 1. The smaller signal swing reduces the amount of time the signal takes to transition between states, thus allowing for faster operational speed.

While FIG. 4A illustrates that the external clock signals 405 are provided only to input buffer 406 of DCC circuit 402, it is understood that the external clock signals 405 may be provided to various components, such that the various components operate in a synchronous manner. For example, the external clock signals 405 may be also provided to other DCC circuits for other memory devices or to other circuits in the same memory device. In some embodiments, as shown in FIG. 4A, the external clock signals 405 may be provided in a differential pair configuration, including a first external clock signal (denoted by p_re_t) and a second external clock signal (denoted by p_re_c). A differential pair provides signals having opposite polarities (e.g., one positive voltage and one negative voltage with respect to a common mode voltage). The usage of the differential pair configuration for the external clock signals 405 may help reduce noise, reduce electromagnetic interference, improve signal integrity, and/or improve speed performance.

In some examples, the DCC circuit 402 receives the external clock signals 405 at an input buffer 406. In some embodiments, the input buffer 406 may include one or more operational amplifiers (op-amps). In some embodiments, the input buffer 406 may include one or more inverters and/or other circuits (e.g., singled-end clock buffers, differential clock buffers, low-skew clock buffers, zero-delay buffers, etc.). The input buffer 406 can be configured (e.g., the p-type transistors and n-type transistors in the input buffer 406 may be sized) to amplify the analog voltage signals. For example, the analog CML logic signals (e.g., the external clock signals 405) can be amplified (therefore strengthened) before they are transmitted to downstream circuits. Strengthening the analog signals can improve the signal integrity and widen the eye opening. As shown in FIG. 4A, the input buffer 406 can be further configured to receive a DCC control signal (e.g., DCC code 415) from a DCC control circuit 414. The DCC control signal 415 can be used to correct the duty cycle errors or duty cycle distortions of the external clock signals 405, without using a reference signal. Thus, the DCC circuit 402 is a self-calibrated circuit without requiring a reference signal. The self-calibrated duty cycle correction loop including the DCC control circuit (or DCC controller) 414 is described in more detail below.

With reference still to FIG. 4A, in some embodiments, the DCC circuit 402 further includes a pair of converters 408 configured to obtain full-swing clock signals based on the amplified external clock signals 405. As described above, the external clock signals 405 may be CML signals. Therefore, the outputs of the input buffer 406 may still be CML signals (e.g., amplified CML signals). In some embodiments, the pair of converters 408 may include CML to complementary metal oxide semiconductor (CMOS) converters (CML-CMOS converters). For example, the pair of converters 408 may include a first CML-CMOS converter and a second CML-CMOS converter for receiving and converting the pair of CML clock signals from input buffer 406. The pair of converters 408 may be configured to convert the analog voltage/current signal to differential outputs suitable for high-speed digital logic. For example, CML generally has a small swing around 0.2V to 0.3V. The small swing may provide high-speed operation and reduced noise, but may be incompatible with other logic circuits that process full swing signals such as CMOS signals. For example, circuits in memory devices such as NAND devices generally use a higher voltage swing (e.g., 1.2V). Thus, these circuits cannot process the CML signals directly. The CML-CMOS converters 408 are configured to convert the CML small swing signals (e.g., 0.2V or 0.3V) to CMOS full swing signals such as between 0V and 1.2V, 0V and 3.3V, 0V and 5V, etc.

The pair of CML-CMOS converters 408 (e.g., including the first CML-CMOS converter and the second CML-CMOS converter) generate complementary CMOS signals based on the CML clock signals from the input buffer 406. For example, the first CML-CMOS converter may generate a direct or a true signal, and the second CML-CMOS converter may generate an inverted or complementary signal. The clock signals generated by the CML-CMOS converters 408 are full-swing clock signals (also referred to as the CMOS signals).

In some embodiments, as shown in FIG. 4A, the full-swing clock signals are provided by the pair of converters 408 to a pair of filters 410. The pair of filters 410 comprises, for example, a first filter and a second filter. The pair of filters 410 can be configured to provide filtered clock signals based on the full-swing clock signals from the pair of converters 408.

In some embodiments, the pair of filters 410 may include low pass filters configured to receive the complementary signals from the pair of converters 408. For example, the first filter and the second filter of the pair of filters 410 are configured to receive the direct signal and the inverted signal from the first CML-CMOS converter and the second CML-CMOS converter, respectively, of the pair of converters 408. The pair of filters 410 can be configured to smooth or reduce the noise present in the direct signal and the inverted signal. For example, the low pass filters included in the pair of filters 410 can pass the low frequency (e.g., DC) signals while filtering out the high frequency transient signals. Therefore, by using the low pass filters, the pair of filters 410 can provide the filtered clock signals that are DC signals. The filtered clock signals from the pair of filters 410 thus may represent the average voltages of the full-swing clock signals provided by the pair of converters 408. If a full-swing clock signal, whether a true signal or a complementary signal), has a desired duty cycle (e.g., 50%), the average voltage of the full-swing clock signal is 0.5*Vcc. Thus, if the filtered clock signals from the pair of filters 410 deviate from the average volage of a signal having a desired duty cycle, the average voltages of the filtered clock signals would be different from 0.5*Vcc. In addition, because the full-swing clock signals provided by the pair of converters 408 are complementary to each other, the average voltages of the filtered clock signals provided by the pair of filters 410 can also have the same offset from the idea average voltage with opposite polarity. For instance, the average voltage of one filtered clock signal may be 0.4*Vcc, while the other average voltage of the other filtered clock signal may be 0.6*Vcc. Thus, when there is duty cycle distortion, the two average voltages represented by the filtered clock signals are different. The two filtered clock signals can therefore be compared using a first comparator 412.

In some embodiments, the DCC circuit 402 further includes a first comparator 412 configured to compare the filtered clock signals to obtain a comparison result. As described above, the pair of filters 410 can be low pass filters, which can output filtered clock signals indicating the average voltages of the full-swing clock signals generated by the pair of converters 408. If there is duty cycle distortion, the two average voltages represented by the filtered clock signals may not be equal and may have a difference. The first comparator 412 can compare the difference between the filtered clock signals and generate an error signal. The error signal is provided to a DCC control circuit 414 for generating a control signal. As shown in FIG. 4A, for determining the error signal, no external reference voltage or signal is used, unlike some conventional DCC circuits. Thus, the DCC circuit 402 is a self-calibrated circuit, which reduces the circuit complexity, eliminates the requirements for providing a precise reference signal, and reduces calibration time. In one embodiment, the first comparator 412 can be a differential amplifier, an op-amp, or other comparator circuit.

With continued reference to FIG. 4A, in some embodiments, DCC circuit 402 further includes a DCC controller 414. The DCC controller 414 is configured to receive the comparison result from the first comparator 412. Based on the comparison result, the DCC controller 414 generates a DCC code 415 for controlling the input buffer 406 to adjust the duty cycle of the buffered clock signals (and in turn the full-swing clock signals generated by the converters 408). For example, the DCC controller 414 receives the error signal from the first comparator 412. If the error signal indicates the duty cycle is low (e.g., 30%), the DCC controller 414 can generate the DCC code 415 to increase the duty cycle, and vice versa. In some examples, based on the error signal, the DCC controller 414 can determine a duty cycle correction (DCC) code (denoted by dcc_code) as the control signal 415. The DCC code 415, in some embodiments, is represented using a five-bit binary representation (e.g., dcc_code[4:0]). For example, the DCC code 415 may include values from 0 to 31 in decimal or 00000 to 11111 in binary, in which 00000 may correspond to maximum adjustment for decreasing the duty cycle and 11111 may correspond maximum adjustment for increasing the duty cycle. Other correspondences of the DCC code 415 are also possible. The DCC controller 414 provides the DCC code 415 to the input buffer 406, such that the input buffer 406 adjusts the output voltage to in turn adjust the duty cycle. In one example, the input buffer 406 may include a set of inverters having p-type transistors and n-type transistors. The DCC code 415 can be used to control the turn on and/or turn off of each of the transistors to increase the duty cycle or decrease the duty cycle as needed. When the duty cycle of the output CML signals from input buffer 406 is adjusted (e.g., increased or decreased), the full-swing clock signals from the converters 408 are also adjusted. Therefore, when the full-swing clock signals from the converters 408 are provided to downstream circuits (e.g., the clock tree 420 and the QEC circuit 404), they are already duty cycle corrected. In conventional circuits, a duty-cycle distorted or skewed clock may be corrected at a later stage. But in that case, the duty cycle distortion or errors may be amplified by subsequent circuits. For instance, a 2% duty cycle error may be amplified to more than 10%. Thus, correcting the duty cycle error at the front stage (e.g., at the input buffer 406) may help reducing the risk of error amplification.

As shown in FIG. 4A, the DCC circuit 402 includes a feedback loop 403. Feedback loop 403 includes the filters 410, the first comparator 412, the DCC control circuit 414, and the input buffer 406. The operation of the feedback loop 403 is described above. In some examples, the feedback loop 403 continuously monitors the duty cycle of the clock signals (e.g., the full-swing clock signals generated by CML-CMOS converters 408). The feedback loop 403 is configured to continuously adjust the duty cycle of the output signals of the input buffer 406 and repeat until the desired duty cycle is reached and/or to compensate for any additional errors or skews with the duty cycle. The feedback loop 403 permits the DCC circuit 402 to monitor and improve the duty cycle of the clock signals without an external reference voltage and in a continuous manner, to provide improved clock signals. The lack of external reference voltage may provide improvements over existing DCC circuits with respect to simplicity, reduced cost, reduced footprint, improved reliability, power supply independence, easier calibration, etc.

With reference still to FIG. 4A, in some embodiments, the DCC circuit 402 further includes a pair of dividers 416 configured to receive the full-swing clock signals from the pair of converters 408 and to divide the clock signals to generate a first clock signal 417a having a first clock phase (denoted as the I phase) and a second clock signal 417b having a second clock phase (denoted as the Q phase). In some embodiments, the pair of dividers 416 includes CMOS dividers configured to divide full-swing clock signals (e.g., CMOS clock signals). For example, the pair of dividers 416 may include a first CMOS divider 416a configured to divide the clock signal to produce the first clock signal 417a having a first phase and a second CMOS divider 416b configured to divide the clock signal to generate the second clock signal 417b having a second phase. The clock signals 417a and 417b may have half the frequency (or a reduced frequency with any ratio) of the full-swing clock signals received by the dividers 416a and 416b. The first clock signal 417a and the second clock signal 417b are phase-shifted from each other. For example, the first CMOS divider 416a receives the true clock signal generated by the first CML-CMOS converter and the second CMOS divider 416b receives the complementary clock signal generated by the second CML-CMOS converter. The first CMOS divider 416a generates the first clock signal 417a based on the true clock signal and the second CMOS divider 416b generates the second clock signal 417b based on the complementary clock signal, resulting in the first clock signal 417a and the second clock signal 417b being phase-shifted from each other. For example, the first clock signal 417a and the second clock signal 417b are phase-shifted by 90 degrees from each other.

In some examples, the DCC circuit 402 further includes a first clock driver 418a and a second clock driver 418b (collectively referred to as clock drivers 418 and denoted as clk driver). The clock drivers 418 are configured to distribute and/or deliver clock signals to various parts of a system or a device. The clock drivers 418 help maintain integrity of clock signals over longer distances without significant degradation. The first clock driver 418a may distribute the first clock signal 417a having a first phase (e.g., I-phase) and the second clock driver 418b may distribute the second clock signal 417b having a second phase (e.g., Q-phase). In some embodiments, the clock drivers 418 delivers the clock signals to a clock distribution circuit (e.g., the clock tree 420) configured to distribute the two-phase clock signals (e.g., the first clock signal 417a and the second clock signal 417b) to multiple lanes of parallel data channels. In some embodiments, each lane of the multiple lanes of parallel data channels is associated with a corresponding QEC circuit of one or more QEC circuits. In other embodiments, a QEC circuit is shared among multiple lanes of parallel data channels.

In some embodiments, the multiple lanes of parallel data channels are organized in pairs to facilitate high-speed data transfers, in which each pair of lanes transmit data in parallel. For example, the multiple lanes of parallel data channels may include a first lane of parallel data channels and a second lane of parallel data channels. The first lane of parallel data channels and the second lane of parallel data channels may be organized in a first pair 440a (e.g., denoted as pad_io_pair 01). The first pair 440a includes the first lane and the second lane, which output data in parallel via pads p_dq<0> and p_dq<1>. Both the first lane and second lane may be associated with a corresponding QEC circuit, such as the QEC circuit 404. Other possible pairs (e.g., a second pair 440b including a third lane and a fourth lane, a third pair 440c including a fifth lane and a sixth lane, a fourth pair 440d including a seventh lane and an eight lane, and a fifth pair 442 including signal check lane and a status lane) may be each associated with a corresponding QEC circuit (not shown). The second pair 440b, third pair 440c, fourth pair 440d, and fifth pair 442 are denoted as pad_io_pair_23, pad_io_pair_45, pad_io_pair_67, and pad_dqs_pair, respectively. In some examples, each pair of lanes shares a QEC circuit. In other examples, multiple pairs of lanes may share one or more QEC circuits. It is understood that there can be any number of lanes of parallel data channels in a device or a system and is not limited to those shown in FIG. 4A. The below descriptions of the QEC circuit uses circuit 404 as an example. It is understood that other QEC circuits can be similarly implemented.

The QEC circuit 404 receives the two-phase clock signals 421 (e.g., the first clock signal 421a having a first phase and second clock signal 421b having a second phase) from the clock tree 420. As described above, the clock tree 420 receives two-phase clock signals from the clock driver 418 and distributes to multiple pairs of lanes of parallel data channels, including the first pair 440a. The clock tree 420 may also distribute the two-phase clock signals to other lanes of parallel data channels 440a-440c and 442. In some examples, the QEC circuit 404 receives the two-phase clock signals 421 via a pair of phase splitters 422 (including 422a and 422b) configured to convert the two-phased clock signals 421 to four clock signals 423 having four different phases. For example, a first clock phase splitter 422a receives the first clock signal 421a having a first phase (e.g., the I-phase), and a second clock phase splitter 422b receives the second clock signal 421b having a second phase (e.g., the Q-phase). The first phase and the second phase may have a 90-degree phase shift between each other. The phase splitters 422 are configured to convert the two clock signals 421 to four clock signals 423. For example, the first phase splitter 422a may split or generate multiple outputs from the first clock signal 421a. For example, the first clock splitter 422a is configured to generate a pair 423a of clock signals having opposite phases. The pair 423a of clock signals include a third clock signal (denoted as IB-phase clock signal) and the first clock signal 421a (denoted as the I-phase clock signal). In the pair 423a of clock signals, the two opposite phase clock signals have a 180-degree phase shift from each other (i.e., the I-phase clock signal is 180-degree phase shifted from the IB-phase clock signal, and vice versa).

Similarly, the second clock splitter 422b is configured to generate a pair 423b of clock signals having opposite phases. The pair 423b of clock signals has a fourth clock phase (denoted as the QB-phase clock signal) and the second clock signal 421b (denoted as the Q-phase clock signal). In the pair 423b of clock signals, the two opposite phase clock signals have a 180-degree phase shift from each other (i.e., the Q-phase clock is 180-degrees shifted from the QB-phase clock signal, and vice versa). As described above, the clock signals 421a and 421b (i.e., the I-phase clock signal and the Q-phase clock signal, respectively) have a 90-degree phase shift between each other. Therefore, in these and other embodiments, the first clock signal (denoted as the I-phase clock signal), the second clock signal (denoted as the Q-phase clock signal), the third clock signal (denoted as the IB-phase clock signal), and the fourth clock signal (denoted as the QB-phase clock signal) are gradually offset by 90 degrees. For example, if the first clock signal has a phase of 0 degree, the second clock signal is offset by 90 degrees from the first clock signal, the third clock signal is offset by 180 degrees from the first clock signal, and the fourth clock signal is offset by 270 degrees from the first clock signal. In some embodiments, the phase splitters 422 may include one or more phase inverters (e.g., an inverter chain), resistor-capacitor (RC) phase splitter, op-amp-based phase splitter, etc.

With continued reference to FIG. 4A, the four-phase clock signals 423 (e.g., pair 423a of signals including the first clock signal and the third clock signal and signals 423b including the second clock phase and the fourth clock signal) are received by a skew adjustor 424 and a shift register 428. The shift register 428 is configured to generate a set of N clock signals based on the four-phase clock signals 423, in which the “N” is greater than four. For example, the shift register 428 may be configured to generate eight clock signals 429 based on the four-phase clock signals, in which the frequencies of the eight clocks signals 429 may be half of the four-phase clock signals 423 and/or may have their phases further shifted. The eight clock signals 429 can be used for converting parallel data to serial data, as described next.

With reference to FIG. 4A, in some examples, each data channel of the first pair 440a of parallel data channels (e.g., the first lane of parallel data channels and the second lane of parallel data channels) associated with the QEC 404 can include a set of multiplexers configured to receive data from the corresponding parallel data channels and to serialize, based on the set of N clock signals (e.g., the eight clock signals) and/or the four-phase clock signals to obtain serialized data. For example, a first set of multiplexers may be configured to obtain data from the first lane of parallel data channels (e.g., from a first FIFO (First In, First Out) 430a), and serialize the data to obtain first-lane serialized data. A second set of multiplexers may be configured to obtain data from the second lane of parallel data channels (e.g., from a second FIFO 430b), and serialize the data to obtain second-lane serialized data. In these and other embodiments, the first channel and the second channel may be identical with respect to components but may vary with respect to the data communicated using the channels.

In these and other embodiments, the set of multiplexers for each data lane can include an 8-to-4 mux and a 4-to-1 mux, as shown in FIG. 4A. For example, the first lane of parallel data channels includes a first 8-to-4 mux 431a and a first 4-to-1 mux 432a, and the second lane of parallel data channels includes a second 8-to-4 mux 431b and a second 4-to-1 mux 432b. As shown in FIG. 4A, the 8-to-4 multiplexers 431a and 431b receive the eight clock signals 429 generated by the shift register 428. Using the eight clock signals, the 8-to-4 multiplexers 431a and 431b combine the data from eight parallel channels to form data in four parallel channels in the first lane and second lane, respectively. In this example, the 4-to-1 multiplexers 432a and 432b receive the skew-adjusted four-phase clock signals 427 generated by the skew adjusters 424. The skew-adjusted four-phase clock signals 427 can be used by the 4-to-1 multiplexers 432a and 432b to combine the data from the four parallel channels to serialized data. The serialized data can be transferred to external of the memory device in a high-speed manner.

In some embodiments, each data lane of parallel data channels includes one or more drivers configured to amplify the serialized data. For example, the first lane (e.g., denoted by DQ0) of parallel data channels includes a first set of drivers 436a and the second lane (denoted by DQ1) of parallel data channels includes a second set of drivers 436b. The first set of drivers 436a is configured to amplify the first-lane serialized data and the second set of drivers 436b is configured to amplify the second-lane serialized data. The amplified first-lane serialized data and the amplified second-lane serialized data can be transmitted to external of the memory device comprising the DCC-QEC circuit 400. In some examples, a driver 436 (e.g., 436a and/or 436b) can include one stage driver and/or a two-stage driver. A two-stage driver may include a pre-driver and a main driver, thereby providing higher amplification gain compared to a one-stage driver.

As described above, the skew adjustor 424 is configured to adjust the four-phase clock signals 423 (including the pair 423a of signals and the pair 423b of signals) to compensate for any skews present among the four clock signals 423 generated by the pair of phase splitters 422. In some embodiments, the skew adjustor 424 is configured to compensate for the skews associated with a subset of four clock signals 423 based on QEC adjustment codes (or simply QEC codes) 426. In other words, unlike conventional closed-loop skew adjustment technologies, where the skews need to be adjusted among all four-phase clock signals, the present disclosure uses the QEC adjustment codes 426 to adjust the skews in an open loop manner. Therefore, skew adjuster 424 only needs to adjust skews of a subset of the four-phase clock signals 423 (e.g., adjust skews among three out of the four-phase clock signals).

In some embodiments, a tester may determine the QEC code 426 based on operations of the QEC circuit 404 in the test mode. In the test mode, the QEC circuit 404 may run primarily using circuits in a test loop 447 of the QEC circuit 404. In the test mode, the skews between a subset of the four clock signals are determined, and the QEC codes 426 are determined based on the skews. In some examples, the test mode is operated only one time (e.g., the first time) to determine the QEC codes 426 for controlling the skew adjustor 424. In other example, following the first run, the test mode operation may repeat, as needed, to adjust the QEC codes 426 to make changes to the skews in the four clock signals 423 and thus generate the skew-adjusted clock signals 427. As described above, the skew-adjusted clock signals 427 can be used for clocking the 4-to-1 multiplexers 432a and 432b for serializing the data. It is understood that the example shown in FIG. 4A is not limiting. For example, if the data lane has more than 8 parallel data channels, a 16-to-8 multiplexer may be used. In another example, there may be only one 8-to-1 multiplexer and not two multiplexers (e.g., an 8-to-4 mux and a 4-to-1 mux). The test mode operations using the circuits in the test loop 447 are described in further detail with reference to FIGS. 4A and 4B.

In some examples, the test mode operation determines the QEC adjustments codes 426, based on which correction of the skews in a subset of the four-phase clock signals 423 can be performed. The test mode operation may also be referred to as a calibration operation. With reference to FIGS. 4A and 4B, the QEC circuit 404 operating in the test mode compares filtered serialized data, which are generated based on the four-phase clock signals 423 to determine the skews. In particular, the comparison may be performed using a second comparator 444 coupled to the QEC circuit 404 associated with the first pair 440a of parallel data lanes. In some examples, the second comparator 444 can be coupled to other QEC circuits associated with other pairs of parallel data lanes (e.g., QEC circuits associated with pairs 440b, 440c, 440d, and/or 442). The second comparator 444 is configured to receive filtered serialized data from the one or more QEC circuits associated with one or more pairs of parallel data lanes and to generate a DCC-QEC monitoring output 446 for the tester.

As shown in FIGS. 4A and 4B, in one example, the serialized data generated by 4-to-1 mux 432 a, and the serialized data generated by 4-to-1 mux 432b are provided to filters 434a and 434b, respectively. Filters 434a and 434b may be low pass filters that can pass low frequency (or DC) signals while filtering out high frequency signals. Thus, in some examples, the outputs from the filters 434a and 434b (also referred to as the filtered serialized data) can each be averaged using the filters 434a and 434b. The two outputs from filters 434a and 434b are provided to second comparator 444. The outputs of the second comparator 444 is provided to the tester (not shown) for monitoring and making adjustments to the QEC codes 426 if necessary. In some examples, as shown in FIG. 4A, the comparator 444 is coupled to all filtered serialized data in multiple pairs of parallel data lanes including the pairs 440a-440d and 442 (e.g., the outputs of filters in pairs 440a-440d and 442). Thus, the filtered serialized data from multiple lanes are averaged and provided to comparator 444. As such, only one comparator 444 is needed and the QEC adjustment codes may be the same for all pairs 440a-440d and 442. Sharing one comparator 444 may reduce power consumption and circuit complexity. In other examples, multiple comparators may be used for multiple pairs of data lanes. In one example, the tester may include a computing device or a controller such as apparatus 300 for monitoring outputs from comparator 444 and making adjustments to the QEC codes 426. As described above, based on the QEC codes 426, the skew adjuster 424 is configured to adjust the time skews among a subset of the four-phase clock signals.

In some embodiments, the skew adjustor 424 comprises a set of single delay lines, in which each delay line of the set of single delay lines is configured to independently adjust a clock skew between two phases of a subset of the four-phase clock signals by delaying a corresponding clock signal. As shown in FIG. 4B, for example, the skew adjustor 424 includes a first delay line 425a associated with one clock signal of the pair 423a of clock signals. This clock signal has a first phase of the four-phase clock signals 423 (e.g., the first delay line is associated with the I-phase clock signal). In some embodiments, the skew adjustor 424 may not necessarily adjust the first clock signal. Accordingly, the first delay line 425a may pass through the first clock signal (e.g., the first delay line 425a may just buffer the clock signals or may just be a transmission line that passes through the clock signal). The skew adjustor 424 further includes a second delay line 425b configured to adjust one clock signal of the pair 423b of clock signals. This clock signal has a second phase of the four-phase clock signals 423 (e.g., the second delay line is associated with the Q-phase clock signal). The skew adjustor 424 may further include a third delay line 425c configured to adjust the other clock signal of the pair 423a of clock signals. This clock signal has a third phase of the four-phase clock signals 423 (e.g., the third delay line is associated with the IB-phase clock signal). The skew adjustor 424 may further include a fourth delay line 425d for adjusting the other clock signal of the pair 423b of clock signals. This clock signal has a fourth phase of the four-phase clock signals 423 (e.g. the fourth delay line is associated with the QB-phase clock signals). In some examples, the four delay lines 425a-425d may each independently adjust time skews between the any two of the four-phase clock signals. And in some examples, only a subset of the four-phase clock signals, but not all, is adjusted using one or more of the four delay lines 425a-425d. For example, as shown in FIG. 4A, the QEC code 426 includes sets of codes corresponding to the second delay line 425b (qec_code_q[4:0]), the third delay line 425c(qec_code_ib[4:0]), and/or the fourth delay line 425d(qec_code_qb[4:0]), but not the first delay line 425a. In some embodiments, the delays lines 425 are or include delay-cell delay line (DCDL), a circuit used to introduce a specific controllable delay to signals using delay cells. Delay cells used in delay lines are frequently implemented using inverters, transistors, or logic gates to control the delay length by adjusting parameters like resistance, capacitance, the size of the inverters, the number of the inverters, etc.

With four-phase clocking, a skew may exist between any set of clock phase signals. For example, a skew may exist between the clock signal having the first phase and the clock signal having the second clock phase, between the clock signal having the first clock phase and the clock signal having the third clock phase, between the clock signal having the first clock phase and the clock signal having the fourth clock phase, between the clock signal having the second clock phase and the clock signal having the third clock phase, between the clock signal having the second clock phase and the clock signal having the fourth clock phase, and between the clock signal having the third clock phase and the clock signal having the fourth clock phase. Adjusting the skews between each possible pair of clock phase signals may not be efficient. To adjust skews in an efficient manner, some embodiments of the present disclosure may adjust time skews between clock signals of three different phases. For example, first, the skew between the clock signal having the first clock phase and the clock signal having the third clock phase may be adjusted by adjusting the third clock phase to match the first clock phase (e.g., adjusting IB-phase to match the I-phase, or vice versa). Second, the clock signal having the second clock phase may be adjusted based on the first clock phase and the third clock phase (e.g., adjusting the Q-phase to match the I-phase and IB-phase). Finally, the fourth clock phase is adjusted based on the third clock phase and the first clock phase (e.g., adjusting the QB-phase to match the I-phase and the IB-phase).

To adjust the skews, the first clock signal having the first clock phase and the third clock signal having third clock phase are compared first. To compare the first clock signal and the third clock signal, a complementary data patterns are provided to the first 4-to-1 mux 432a and the second 4-to-1 mux 432b. For example, a first data mux 433a may be coupled to the first 4-to-1 mux 432a and a second data mux 433b may be coupled to the second 4-to-1 mux 432b. A data select input 445 (denoted as data_sel) selects the data pattern to be used. For example, the data select input selects a pattern “1100” for the first data mux 433a and the data select input selects a pattern “0011” for the second data mux 433b.

Such complementary data patterns cause the data patterns of the first lane and the second lane of the parallel data channels to be presented in an aligned manner, with respect to timing, for direct comparison (e.g., using the second comparator 444). FIG. 4C illustrates a timing diagram 450 representing four clock signals having four different phases. The diagram 450 includes a first clock signal 452 having a first phase, a second clock signal 454a having a second phase, a third clock signal 456a having a third phase, and a fourth clock signal 458a having a fourth phase. The four clock signals may be gradually offset by 90 degrees. For example, the first clock signal 452 may correspond to the I-phase clock signal, the second clock signal 454a may correspond to the Q-phase clock signal, the third clock signal 456a may correspond to the IB-phase clock signal, and the fourth clock signal 458a may correspond to the QB-phase clock signal, such as described with respect to FIG. 4B.

With reference to FIG. 4C, the first clock signal 452 represents a clock signal output by the first 4-to-1 mux 432a using the “1100” pattern, and the third clock signal 456a represents a clock signal output by the second 4-to-1 mux 432b with the second data pattern “0011”. The first clock signal 452a and the third clock signal 456a are generated in a complementary manner such that the rising edges of the first clock signal 452 are supposedly aligned with the falling edges of the third clock signal 456a. In these and other embodiments, a rising edge of the first clock signal 452 is compared with a rising edge of the third clock signal 456a to determine a first skew (denoted as x) between the first clock signal 452 and the third clock signal 456a. For example, with reference back to FIG. 4B, the second comparator 444 is configured to receive a first output (e.g., the first clock signal 452) from the first 4-to-1 mux 432a and a second output (e.g., the third clock signal 456a) from the second 4-to-1 mux 432b. The second comparator 444 generates the monitoring output 446 based on the comparison of the first output and the second output. For example, when the first clock signal 452 is high and the third clock signal 456a is low, the monitoring output 446 of the second comparator 444 is high. When the first clock signal 452 is low and the third clock signal 456a is high, the monitoring output 446 is low.

The tester performs or causes analysis of the monitoring output 446 to determine the time difference or a first skew between the rising edges of the first clock signal 452 and the third clock signal 456a based on the monitoring output 446. Based on the first skew, the tester determines the QEC code 426 associated with the third clock signal 456a. For example, the QEC code 426 may define how to adjust the third clock signal 456a to compensate for the first skew. The tester provides the QEC code 426 to the skew adjustor 424, such that the skew adjustor 424 may adjust the third clock signal 456a using the third delay line 425c. The third delay line 425c is used to create a delay in digital signals such as the third clock signal 456a. For instance, a delay compensating for the first skew may be applied to the third clock signal 456a to generate the adjusted third clock signal 456b. The adjusted third clock signal 456b may be aligned with the first clock signal 452.

After adjusting the third clock signal 456a to be adjusted third clock signal 456b based on the QEC code 426, a second skew (denoted as y in FIG. 4C) between in the second clock signal 454a and the first clock signal 452 and the adjusted third clock signal 456b is identified and adjusted. In these and other embodiments, the clock signals are generated using an imbalanced data pattern. Using a balanced data pattern or complementary pattern data leads to direct measurement between the first clock signal 452 and the second clock signal 454a. An imbalanced pattern, in which only one bit of the four bits is 1 (or high) may permit identification of the second skew with respect to the first clock signal 452 and the adjusted third clock signal 456b.

With reference back to FIG. 4B, imbalanced data patterns including unequal number of “0” and “1” are provided to the first 4-to-1 mux 432a and the second 4-to-1 mux 432b. For example, the data select input for the first data mux 433a and the second data mux 433b may be determined such that the first data mux 433a provides a third data pattern (e.g., “1000”) to the first 4-to-1 mux 432a, and the second data mux 433b provides a fourth data pattern (e.g., “0100”) to the second 4-to-1 mux 432b. The outputs of the first 4-to-1 mux 432a and the second 4-to-1 mux 432b are received by the second comparator 444. The second comparator 444 compares the outputs to generate the monitoring output 446 for the tester.

With reference to FIG. 4C, the second skew is measured by comparing rising edges of the second clock signal 454a to the rising edges of the first clock signal 452 and then comparing the rising edges of the second clock signal 454a to the rising edges of the adjusted third clock signals 456b. The second clock signal 454a may be offset from the first clock signal 452 and/or the adjusted third clock signal 456b by the second skew. With reference back to FIG. 4B, in such instances, the second comparator 444 may generate the monitoring output 446 based on the comparisons. The tester may determine the QEC code 426 to compensate for the second skew. The QEC code 426 is provided to the skew adjustor 424. The skew adjustor 424 applies a delay to the second clock signal 454a (or the second clock signal 417b) using the second delay line 425b to compensate for the second skew. For example, the second clock signal 454a may be adjusted to be adjusted second clock signal 454b.

Finally, the skew adjustor 424 may identify and adjust a third skew (denoted as z in FIG. 4C) present with respect to the fourth clock signal having a fourth phase (e.g., QB-phase signal). The third skew is present in the fourth clock signal with respect to the third clock signal (e.g., adjusted third clock signal 456b) and the first clock signal (e.g., the first clock signal 452). In these and other embodiments, imbalanced data patterns are provided to the first 4-to-1 mux 432a and the second 4-to-1 mux 432b for identification of the third skew. For example, the data select input for the first data mux 433a and the second data mux 433b may be determined such that the first data mux 433a provides a fifth data pattern (e.g., “0010”) to the first 4-to-1 mux 432a, and the second data mux 433b provides a sixth data pattern (e.g., “0001”) to the second 4-to-1 mux 432b. The outputs of the first 4-to-1 mux 432a and the second 4-to-1 mux 432b are received by the second comparator 444. The second comparator 444 compares the outputs to generate the monitoring output 446 for the tester.

With reference to FIG. 4C, the third skew is measured by comparing rising edges of the fourth clock signal 458a to the rising edges of the adjusted third clock signal 456b and then comparing the rising edges of the fourth clock signal 458a to the rising edges of the first clock signal 452. The fourth clock signal 458a may be offset from the adjusted third clock signal 456b by the third skew. With reference back to FIG. 4B, in such instances, the second comparator 444 may generate the monitoring output 446 based on the comparisons. The tester may determine the QEC code 426 to compensate for the third skew. The QEC code 426 is provided to the skew adjustor 424. The skew adjustor 424 applies a delay to the fourth clock signal (e.g., the fourth clock signal 458a) using the fourth delay line 425d to compensate for the third skew. For example, the fourth clock signal 458a may be adjusted to be adjusted fourth clock signal 458b.

With continued reference to FIG. 4B, as described above, in some embodiments, the QEC circuit 404 further includes one or more filters configured to filter the serialized data obtained from respective lane of the multiple lanes of parallel data channels. For example, the QEC circuit 404 may include a first QEC filter 434a configured to filter the first-lane serialized data, and a second QEC filter 434a configured to filter the second-lane serialized data. In some embodiments, the one or more filters may be or include low pass filters. The one or more filters are configured to adjust and/or compensate for the skew that may be introduced after adjusting the skew (e.g., via the skew adjustor 424). For example, the one or more filters may adjust and/or compensate the skew introduced by the 4-to-1 muxes.

The adjustments of the first skew, the second skew, and the third skew individually, as described above, may permit skew adjustment 424 with a reduced number of delays to the clock signals compared to some traditional approaches. For example, no delays are made for the first clock signal, one adjustment compensating for the first skew is made to the third clock signal, one adjustment compensating for the second skew is made to the second clock signal, and one adjustment compensating for the third skew is made to the fourth clock signal. Such reduced number of adjustments may help reduce number and/or footprint of physical components. For instance, some traditional approaches require multiple adjustments to each clock phase signals such that multiple delays lines are needed per clock phase, which respectively requires additional physical components and adds complexity and/or power consumption.

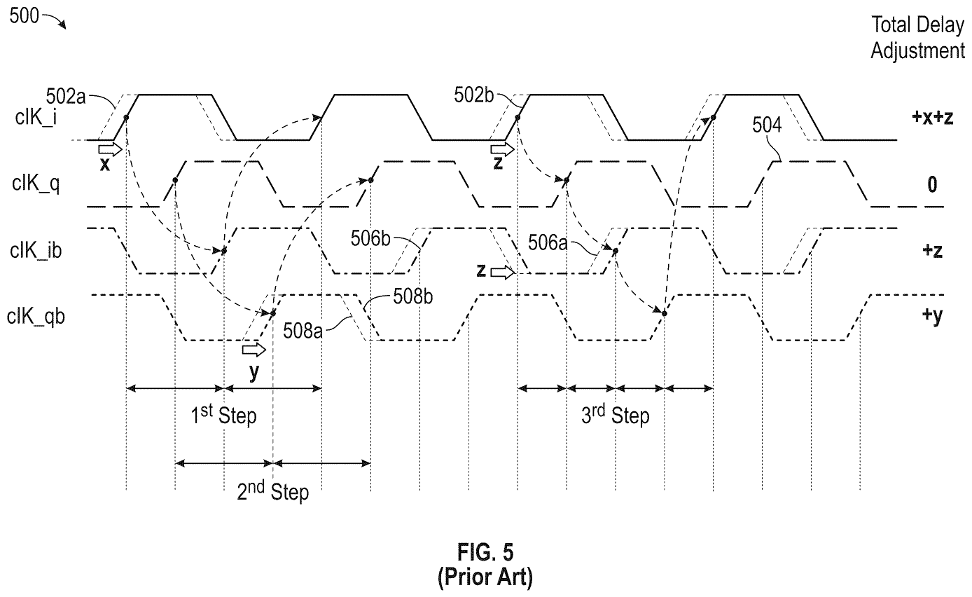

For example, FIG. 5 illustrates a diagram 500 illustrating skew adjustment process for at least one traditional approach. The diagram 500 illustrates a first clock signal 502a having a first phase, a second clock signal 504 having a second phase, a third clock signal 506a having a third phase, and a fourth clock signal 508a having a fourth phase. The clock signals may correspond to the clock signals discussed with respect to FIG. 4C. However, the skews present in the clock signals are adjusted in a different approach. For instance, with the at least one traditional approach, the first clock signal 502a and the third clock signal 506a are compared. In such instances, complementary data patterns (e.g., “1100” and “0011”) are used for the first clock signal 502a and the third clock signal 506a to directly compare the clock signals. Based on the comparison, the first clock signal 502a is adjusted to be aligned with the third clock signal 506a. For example, a QEC code adjusting the skew is provided to a skew adjustor. The skew adjustor includes a first delay line, a second delay line, a third delay line, and a fourth delay line corresponding to the first clock signal 502a, the second clock signal 504, the third clock signal 506a, and the fourth clock signal 508a, respectively. Each delay line includes multiple delay units. Each delay unit may adjust the delay of the respective clock signal at an instance. For example, one of the multiple delay units of the first delay line is used to delay the first clock signal 502a to be aligned with the third clock signal 506a.

Following the adjustment of the first clock signal 502a with respect to the third clock signal 506a, the second clock signal 504 and the fourth clock signal 508a are compared. To directly compare the second clock signal 504 and the fourth clock signal 508a, complementary data patterns (e.g., “0110” and “1001”) are used. An offset between the second clock signal 504 and the fourth clock signal 508a is identified and the fourth clock signal 508a is adjusted based on the offset. For example, at least one delay unit of the fourth delay line is used to cause a delay to the fourth clock signal 508a to be adjusted fourth clock signal 508b. Such a delay may align the second clock signal 504 and the adjusted fourth clock signal 508b.

Finally, during the last step, skews between the first clock signal 502a and the second clock signal 504, between the second clock signal 504 and the third clock signal 506a, between the third clock signal 506a and the fourth clock signal 508a, and between the fourth clock signal 508a and the first clock signal 502a are determined using another set of complementary data patterns (e.g., “1010” and “0101”). The skews are used to determine the offset between a first group of clock signals (e.g., the first clock signal 502a and the third clock signal 506a) and a second group of clock signals (e.g., the second clock signal 504 and the adjusted fourth clock signal 508b).

Based on the offset, the first clock signal 502a and the third clock signal 506a are adjusted to be aligned with the second clock signal 504 and the adjusted fourth clock signal 508b. For example, one of the delay units of the first delay line is used to adjust the first clock signal 502a to be adjusted first clock signal 502b and the third delay line is used to adjust the third clock signal 506a to be adjusted third clock signal 506b. As the first clock signal 502a is first adjusted with respect to the third clock signal 504a and then adjusted again with respect to the second clock signal 504 at a later time, the first delay line requires multiple delay lines which introduces more random variables. Additionally, as the first clock signal 502a and the third clock signal 506a are adjusted at the same time for the same amount, the adjustment may not compensate for any delay (e.g., caused by random mismatch) between the first clock signal 502a and the third clock signal 506a. The traditional circuits for adjusting skews are thus cumbersome, complex, and inefficient.

Returning to FIG. 4A, in some embodiments, to reduce the test time of running the QEC 404 in the test mode, the one or more QEC circuits may be connected to the same second comparator 444. For instance, instead of adjusting the skews of each of the one or more QEC circuits individually, the skews across the one or more QEC circuits are adjusted as a group. For example, the skews for the QEC circuit 404 associated with first pair 440a of data lanes, a second QEC circuit associated with second pair 440b of data lanes (e.g., associated with a third channel and a fourth channel), a third QEC circuit associated with third pair 440c of data lanes (e.g., associated with a fifth channel and a sixth channel), a fourth QEC circuit associated with fourth pair 440d of data lanes (e.g., associated with a seventh channel and an eight channel), and a fifth QEC circuit associated with fifth pair 442 of data lanes (e.g., associated with a signal check lane and a status lane) may be adjusted at the same time. In these and other embodiments, the serialized data from the one or more QEC circuits are combined and/or averaged prior to being fed into the second comparator 444. The second comparator 444 compares the combined serialized data to identify the skews between different clock phase signals, and accordingly determines the QEC code 426 to be distributed to each of the one or more QEC circuits. For instance, the steps of adjusting the skews described above with respect to FIGS. 4A-4C may be repeated using averaged data from the one or more QEC circuits. The combined implementation may improve testing time and efficiency of running the one or more QEC circuits in testing mode.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. Hybrid duty-cycle correction and quadrature error correction (DCC-QEC) circuitry, comprising:
a DCC circuit configured to generate two-phase clock signals based on external clock signals, the DCC circuit being self-calibratable without receiving a reference signal; and
one or more QEC circuits coupled to the DCC circuit, each of the QEC circuit comprising:
a pair of phase splitters configured to convert the two-phase clock signals to four-phase clock signals,
a skew adjuster configured to adjust, based on a set of QEC adjustment codes and in an open loop manner, clock skews associated with a subset of the four-phase clock signals,
wherein data from multiple lanes of parallel data channels are serialized based on the skew-adjusted four-phase clock signals and transmitted to external of a device comprising the hybrid DCC-QEC circuitry.

2. The circuitry of claim 1, wherein the DCC circuit comprises:
an input buffer configured to receive the external clock signals;
a pair of converters configured to obtain full-swing clock signals based on the external clock signals;
a pair of filters configured to provide filtered clock signals based on the full-swing clock signals;
a comparator configured to compare the filtered clock signals to obtain a comparison result; and
a DCC controller configured to control, based on the comparison result, the input buffer to adjust a duty cycle of the full-swing clock signals.

3. The circuitry of claim 2, wherein the full-swing clock signals comprise complementary clock signals enabling self-calibration of the DCC circuit without receiving the reference signal.

4. The circuitry of claim 2, wherein the pair of converters are current-mode logic (CML) to complementary metal-oxide-semiconductor (CMOS) type converters.

5. The circuitry of claim 1, wherein the DCC circuit is coupled to a clock distribution circuit configured to distribute the two-phase clock signals to the multiple lanes of parallel data channels, wherein each lane of the multiple lanes is associated with a corresponding QEC circuit of the one or more QEC circuits.

6. The circuitry of claim 1, wherein the multiple lanes of parallel data channels further comprise:
a first lane of parallel data channels and a second lane of parallel data channels;
a shift register configured to generate a set of N clock signals based on the four-phase clock signals, wherein the “N” is greater than four;
a first set of multiplexers configured to:
receive data from the first lane of parallel data channels; and
serialize, based on the set of N clock signals and the four-phase clock signals, the data from the first lane to obtain first-lane serialized data; and
a second set of multiplexers configured to:
receive data from the second lane of parallel data channels; and
serialize, based on the set of N clock signals and the four-phase clock signals, the data from the second lane to obtain second-lane serialized data.

7. The circuitry of claim 6, wherein the multiple lanes of parallel data channels further comprise one or more drivers configured to amplify the first-lane serialized data and the second-lane serialized data to form the data transmitted to external of the device comprising the hybrid DCC-QEC circuitry.

8. The circuitry of claim 1, wherein each of the one or more QEC circuits further comprises:
a plurality of filters configured to filter serialized data obtained from a respective lane of the multiple lanes of parallel data channels.

9. The circuitry of claim 8, further comprising:
a comparator coupled to the one or more QEC circuits, the comparator being configured to receive filtered serialized data from the one or more QEC circuits and generate a DCC-QEC monitoring output.

10. The circuitry of claim 9, wherein the QEC adjustment codes are determined based on the DCC-QEC monitoring output.

11. The circuitry of claim 1, wherein the skew adjuster comprises a plurality of single delay lines, and each of the plurality of single delay lines is configured to independently adjust a clock skew between two phases of the subset of the four-phase clock signals.

12. The circuitry of claim 1, wherein the skew adjuster is configured to adjust the clock skews associated with the subset of the four-phase clock signals based on data patterns containing unequal numbers of “0” and “1”.

13. The circuitry of claim 1, wherein the subset of the four-phase clock signals comprises three clock signals having different phases.

14. A memory device, comprising:
a controller configured to receive external clock signals; and
a hybrid duty-cycle correction and quadrature error correction (DCC-QEC) circuitry comprising:
a DCC circuit configured to generate two-phase clock signals based on external clock signals, the DCC circuit being self-calibratable without receiving a reference signal; and
one or more QEC circuits coupled to the DCC circuit, each of the QEC circuit comprising:
a pair of phase splitters configured to convert the two-phase clock signals to four-phase clock signals,
a skew adjuster configured to adjust, based on a set of QEC adjustment codes and in an open loop manner, clock skews associated with a subset of the four-phase clock signals,
wherein data from multiple lanes of parallel data channels are serialized based on the skew-adjusted four-phase clock signals and transmitted to external of a device comprising the hybrid DCC-QEC circuitry,
wherein the hybrid DCC-QEC circuitry is coupled to the controller to generate the skew-adjusted four-phase clock signals.

15. The memory device of claim 14, further comprising:
a clock tree coupled to distribute two-phase clock signals to the one or more QEC circuits associated with the multiple lanes of parallel data channels, the two-phase clock signals being duty-cycle corrected clock signals.

16. A memory system comprising a memory device comprising:
a controller configured to receive external clock signals; and
a hybrid duty-cycle correction and quadrature error correction (DCC-QEC) circuitry comprising:
a DCC circuit configured to generate two-phase clock signals based on external clock signals, the DCC circuit being self-calibratable without receiving a reference signal; and
one or more QEC circuits coupled to the DCC circuit, each of the QEC circuit comprising:
a pair of phase splitters configured to convert the two-phase clock signals to four-phase clock signals,
a skew adjuster configured to adjust, based on a set of QEC adjustment codes and in an open loop manner, clock skews associated with a subset of the four-phase clock signals,
wherein data from multiple lanes of parallel data channels are serialized based on the skew-adjusted four-phase clock signals and transmitted to external of a device comprising the hybrid DCC-QEC circuitry,
wherein the hybrid DCC-QEC circuitry is coupled to the controller to generate the skew-adjusted four-phase clock signals.
